(19) United States
(12) Patent Application Publication
(10) Pub. No.: US 2002/0000597 A1
(43) Pub. Date: Jan. 3, 2002

(54) Nonvolatile semiconductor memory device and method for recording information

(76) Inventor: Takeshi Okazawa, Tokyo (JP)

Correspondence Address: McGinn & Gibb, PLLC, 8321 Old Courthouse Road, Suite 200, Vienna, VA, 22182-3817, US

(21) Appl. No.: 09/880,913

(22) Filed: Jun. 15, 2001

(30) Foreign Application Priority Data
Jun. 30, 2000 (JP) 2000-199590

(51) Int. Cl. H01L 27/108; H01L 29/76

(52) U.S. Cl. 257/298; 257/296; 257/903

(57) ABSTRACT

A nonvolatile semiconductor memory device has its output signals widely separated from each other to ensure its proper operation, does not require any high-accuracy resistance generating element, and realizes a high density memory capacity due to its simplememory cell construction in which provided are: a first wiring (21); a second wiring (25) perpendicular to the first wring (21); a third wiring (35) parallel to the first wiring (21); a first memory element (28) between the first wiring (21) and the second wiring (25); and, a second memory element (38) between the second wiring (25) and the third wiring (35). Each of the memory elements (28, 38) includes an insulation film (13) sandwiched between two layers each constructed of a ferromagnetic thin film. The first memory element (28) stores data different from that stored in the second memory element (38).

### BACKGROUND OF THE INVENTION

1. Field of the Invention

The present invention relates to an electrically-erasable nonvolatile semiconductor memory device and a method for recording information in the memory device, and more particularly to a nonvolatile semiconductor memory device and a method of manufacturing the same, wherein the memory device is constructed of memory cells, each of which cells is constructed of magnetoresistive elements formed of ferromagnetic thin films.

2. Description of the Related Art

Of electrically-erasable nonvolatile semiconductor memory devices of the conventional type known in the art, one having its memory cells constructed of magnetoresistive elements which are formed of ferromagnetic thin films is called a “Magnetic Random Access Memory” (hereinafter referred to as MRAM).

FIGS. 4(a), 4(b) and 4(c) are schematic views of an example of the memory element of such an MRAM described above, wherein: FIG. 4(a) is a schematic perspective view of the memory cell, illustrating the memory element in construction; FIG. 4(b) is a schematic perspective view of the essential part of the memory cell, illustrating a data read operation performed in the memory element; and, FIG. 4(c) is a schematic side view of the essential part of the memory element, illustrating a data write operation of the memory cell. As shown in FIG. 4(a), in this memory element, a fixed or pinned layer 12 is formed from a ferromagnetic thin film having a thickness of approximately 20 nm, and has the direction of its magnetization fixed or pinned. The thus pinned layer 12 is disposed on an under lying wiring 11 to as sume a predetermined position thereon. Disposed on this pinned layer 12 is an insulation layer 13 having a thickness of approximately 2 nm. Further disposed on the insulation layer 13 is a data storage layer 14 formed from a ferromagnetic thin film, which film has a thickness of approximately 20 nm and is variable in direction of its magnetization. Still further disposed on the data storage layer 14 is an overlying wiring 15 which extends in a direction perpendicular to the underlying wiring 11.

As shown in FIG. 4(c), in the write operation of the memory element described above, binary information is stored through a switching operation in which the direction of the magnetization of the data storage layer 14 is switched from a “parallel (which corresponds to data 1)” magnetization state to an “antiparallel(which corresponds to data 0)” magnetization state with respect to the direction of the magnetization of the pinned layer 12 by an application of an external magnetic field. At this time, due to the presence of a so-called magnetoresistive effect, a value in electric resistance of the insulation film 13 in the “parallel” magnetization state varies within a range of from approximately 10 to approximately 40 percent of the electric resistance value of the insulation film 13 in the “antiparallel” magnetization state.

As shown in FIG. 4(b), a data read operation of the binary information thus stored in the memory element through the above write operation is realized by applying a predetermined potential difference between the overlying wiring 15 and the underlying wiring 11 to allow a tunnel current to flow from the underlying wiring 11 to the overlying wiring 15 through the pinned layer 12, insulation layer 13 and the data storage layer 14. In other words, since the insulation layer 13 has its electric resistance value vary depending on each of the “parallel” and the “antiparallel” magnetization states of the data storage layer 14 relative to the direction of magnetization of the pinned layer 12 due to the presence of the tunneling magnetoresistive effect (hereinafter referred to as “TMR”), it is possible to retrieve the thus stored information by sensing a variation in the above-mentioned tunnel current.

The memory element shown in FIGS. 4(a) and 4(b) utilizes the tunneling magnetoresistive effect (TMR), and is therefore simpler in construction as to an electrode for retrieving stored information than a memory element utilizing the Giant magnetoresistive effect (hereinafter referred to as “GMR”). Due to this, the memory element utilizing the TMR is advantageous in fabricating an MRAM device having a high density memory capacity.

FIG. 5 is a schematic view illustrating an MRAM device in which a plurality of memory elements 17 are arranged in a matrix form at points of intersection of a plurality of the overlying wirings 15 (called “bit lines”) and the underlying wirings 11 called (“word lines”). Any one of the memory elements 17 can be identified by selecting both a predetermined one of the word lines (i.e., underlying wirings) 11 and a predetermined one of the bit lines (i.e., overlying wirings) 15. After completion of the write operation of information performed in each of the memory elements 17, it is possible to retrieve the thus stored information from the memory element 17 by sensing a tunnel current which flows from the word line 11 and the bit line 15 connected with the memory element 17. One of conventional memory elements of this kind is disclosed in Japanese Patent application Laid-Open No. 2000-82791. Also in such a conventional memory element disclosed in construction, information stored therein is sensed as a variation in tunnel current flowing through a magnetic tunnel junction (hereinafter referred to as “MTJ”) formed between an underlying wiring and an overlying wiring of the memory element.

As described above, the MRAM device utilizing the TMR is constructed of a megnetoresistive element which has a multilayered structure including three or more layers including an insulation film sandwiched between two layers (in general) each of which is constructed of a ferromagnetic thin film. In operation, when the ferromagnetic thin films are subjected to an external magnetic field, these ferromagnetic thin films become “parallel” or “antiparallel” to each other in direction of magnetization thereof, which results in a tunnel current. This tunnel current flows through the insulation film, an electric resistance of which varies to enable the individual memory elements of the MRAM device to store binary information “1” or “0” therein.

However, such an electric resistance of the insulation film caused by the magnetoresistive effect varies usually within a range of from approximately 30 percent up to its maximum value of approximately 40 percent, and is therefore relatively small in value. Further, as shown in FIG. 5, when a plurality of the memory elements 17 are arranged in a matrix form at points of intersection of the overlying wirings 15 (called “bit lines”) and the underlying wirings 11 called (“word lines”), a predetermined or selected one of the memory cell 17 from which necessary information should be retrieved is adversely affected by noise caused by the word lines and the bit lines both of which are not selected. This impairs the functioning of such a selected memory cell 17 in its read current ratio (i.e., a ratio of signal/noise), and often leads to a malfunction thereof. Particularly, as shown in FIG. 5, in the case where a large-capacity memory device having a large number of the memory cells 17 arranged in a matrix form therein is produced, values in electric resistance of the individual memory cells 17 of the memory device often vary widely due to, primarily, the presence of various variations involved in the production of the memory device.

Due to this, a sensing means used in such a conventional type of the nonvolatile semiconductor memory device requires high-accuracy circuitry in construction. Further, the conventional type memory device has the disadvantage that it takes too much time in retrieving information from the memory cells with a high degree of accuracy. Employed in a means for improving the memory cell in read accuracy is a resistance value generating element, for example. This element is used for reference purposes in sensing the variations in absolute values of electric resistance of the individual memory cell. However, such high-accuracy type resistance value generating element is costly in fabrication, and therefore increases the manufacturing cost of the entire memory device. Further, the provision of such high-accuracy type resistance value generating element makes the memory device poor in read operation.

As for the above problems inherent in the MRAM, for example, Japanese Patent application Laid-Open No. Hei 10-177783 discloses a technique for solving the problems, in which technique: as disclosed in the above official gazette, one memory cell is constructed of a pair of memory elements; information is stored in this memory cell; and, a difference in current flowing through the memory cell is sensed as the information.

Problems to be solved by the present invention are as follows: namely, the technique disclosed in the Japanese Patent application Laid-Open No. Hei 10-177783 still suffers from the following problems. Although a magnetic memory cell of an MRAM according to the disclosed technique utilizes the GMR effect, in order to retrieve stored information it is necessary for the memory cell to sense variations in electric resistance by using an electric current which flows in a direction parallel to the direction of magnetization. Consequently, as shown in FIG. 1 of the Japanese Patent application Laid-Open No. Hei 10-177783 official gazette, it is necessary for the disclosed technique to form a resistance value sensing electrode on a side surface of an information recording portion (electroresistive element). Furthermore, in such a memory device of the disclosed technique, when an upper and a lower memory elements of the memory device are stacked together in construction, a plurality of lead wires connected with these memory cells are required, which makes the memory device complex in construction. Consequently, the memory cells of the disclosed technique are not adapted for components of an information memory device which is constructed of a large number of memory cells.

### SUMMARY OF THE INVENTION

In view of the above problems, the present invention was made. Consequently, it is an object of the present invention to provide a nonvolatile semiconductor memory device and a method for recording information in the memory device, wherein the memory device has its output signals widely separated from each other to ensure its proper operation, does not require any high-accuracy resistance value generating element, and realizes a high density memory capacity due to its simple memory cell construction.

In accordance with a first aspect of the present invention, the above object of the present invention is accomplished by providing:

A nonvolatile semiconductor memory device comprising:

a first wiring extending in a first direction;

a first memory element so arranged as to be connected with the first wiring;

a second wiring extending in a second direction which is different from the first direction, the second wiring being connected with the first memory element;

a second memory element so arranged as to be connected with the second wiring;

a third wiring extending in the first direction, the third wiring being connected with the second memory element;

wherein the first memory element is constructed of an insulation film and two or more of ferromagnetic thin films disposed adjacent to opposite sides of the insulation film, the ferromagnetic thin films disposed adjacent to one of the opposite sides of the insulation film being connected with the first wiring while the ferromagnetic thin films disposed adjacent to the other of the opposite sides of the insulation film being connected with the second wiring;

wherein the second memory element is constructed of an insulation film and two or more of ferromagnetic thin films disposed adjacent to opposite sides of the insulation film, the ferromagnetic thin films disposed adjacent to one of the opposite sides of the insulation film being connected with the second wiring while the ferromagnetic thin films disposed adjacent to the other of the opposite sides of the insulation film being connected with the third wiring;

wherein a difference in magnetization direction between the two or more of the ferromagnetic thin films is stored as a piece of information, the piece of information being retrieved by using variations in electric resistance value of the memory element when a tunnel current flows through the memory element, the variations in electric resistance value of the memory being caused by a magnetoresistive effect resulted from the difference in direction between the magnetizations of the two or more of the ferromagnetic thin films;

wherein the first memory element pairs off with the second memory element without exception to store a piece of information opposed in meaning to that stored in the second memory element.

In the prior art, one memory element is provided between a pair of wirings to permit a tunnel current to flow through the memory element, so that the absolute value of an electric resistance of the memory element is detected. In contrast with this, in the present invention, two memory elements are disposed between adjacent two of three wirings to store a plurality of data which are different from each other, each of the data being stored in each of the memory elements, wherein a difference between tunnel currents each of which flows through each of the memory elements is sensed. In other words, in the present invention, since a relative variation in electric resistance value is sensed, it is possible to increase the width of the variation, which facilitates the read operation of the information. Further, since a memory cell constructed of these memory elements is simple in construction, it is possible to fabricate a large-scale nonvolatile semiconductor memory device by integrating these memory cells in an easy manner.

In the nonvolatile semiconductor memory device of the present invention, preferably, a plurality of each of the first, the second and the third wirings and a plurality of each of the first and the second memory elements are provided;

a write circuit connected with the first, the second and the third wiring to store the piece of information in both the first and the second memory element; and

a read circuit connected with the first, the second and the third wiring to retrieve the piece of information stored in the first and the second memory element.

Further preferably, the first direction is perpendicular to the second direction.

Still further preferably, the first wirings are arranged in parallel to each other on a first plane;

the second wiring are arranged in parallel to each other on a second plane, the second plane being parallel to the first plane and disposed over the first plane;

the third wirings are arranged in parallel to each other on a third plane, the third plane being parallel to the first plane and disposed over the second plane;

the first memory elements are disposed on a forth plane, the forth plane being parallel to the first plane and disposed between the first and the second plane;

the second memory elements are disposed on a fifth plane, the fifth plane being parallel to the first plane and disposed between the second and the third plane.

Preferably, each of the write circuit and the read circuit is constructed of a semiconductor integrated circuit.

Further preferably, a plurality of groups, each of which is constructed of the first, the second and the third wiring and the first and the second memory element, are arranged through the insulation films.

According to a second aspect of the present invention, the above object of the present invention is accomplished by providing:

In a method for recording information in a nonvolatile semiconductor memory device comprising: a first wiring extending in a first direction; a first memory element so arranged as to be connected with the first wiring; a second wiring extending in a second direction which is different from the first direction, the second wiring being connected with the first memory element; a second memory element so arranged as to be connected with the second wiring; a third wiring extending in the first direction, the third wiring being connected with the second memory element;

wherein the first memory element is constructed of an insulation film and two or more of ferromagnetic thin films disposed adjacent to opposite sides of the insulation film, the ferromagnetic thin films disposed adjacent to one of the opposite sides of the insulation film being connected with the first wiring while the ferromagnetic thin films disposed adjacent to the other of the opposite sides of the insulation film being connected with the second wiring; the second memory element is constructed of an insulation film and two or more of ferromagnetic thin films disposed adjacent to opposite sides of the insulation film, the ferromagnetic thin films disposed adjacent to one of the opposite sides of the insulation film being connected with the second wiring while the ferromagnetic thin films disposed adjacent to the other of the opposite sides of the insulation film being connected with the third wiring; a difference in magnetization direction between the two or more of the ferromagnetic thin films is stored as a piece of information, the piece of information being retrieved by using variations in electric resistance value of the memory element when a tunnel current flows through the memory element, the variations in electric resistance value of the memory being caused by a magneto resistive effect resulted from the difference in direction between the magnetizations of the two or more of the ferromagnetic thin films; the first memory element pairs off with the second memory element without exception to store a piece of information opposed in meaning to that stored in the second memory element,

the improvement therewith comprising the steps of:

magnetizing one or more of the ferromagnetic thin films of the first memory element in a direction parallel to or antiparallel to a direction of magnetization of the remaining ones of the ferromagnetic thin films other than the one or more of the ferromagnetic thin films to perform an information write operation in the nonvolatile semiconductor memory device; and

magnetizing one or more of the ferromagnetic thin films of the second memory element in a direction parallel to or antiparallel to a direction of magnetization of the remaining ones of said ferromagnetic thin films other than said one or more of said ferromagnetic thin films to perform said write operation of said piece of information in the nonvolatile semiconductor memory device;

wherein: one of a first state and a second state is selected to perform the write operation; the first state is established when the one or more of the ferromagnetic thin films of the first memory element are magnetized in a direction parallel to a direction of magnetization of the remaining ones of the ferromagnetic thin films of the first memory element in a condition in which the one or more of the ferromagnetic thin films of the second memory element are magnetized in a direction antiparallel to a direction of magnetization of the remaining ones of the ferromagnetic thin films of the second memory element; and, the second state is established when the one or more of the ferromagnetic thin films of the first memory element are magnetized in a direction antiparallel to a direction of magnetization of the remaining ones of the ferromagnetic thin films of the first memory element in a condition in which the one or more of the ferromagnetic thin films of the second memory element are magnetized in a direction parallel to a direction of magnetization of the remaining ones of the ferromagnetic thin films of the second memory element;

wherein an information read operation of the nonvolatile semiconductor memory device is performed through the steps of: determining a first electric resistance value of the first memory element when the tunnel current flows through the first memory element; determining a second electric resistance value of the second memory element when the tunnel current flows through the second memory element; and, sensing a difference in electric resistance value between the first and the second electric resistance value to determine which of the first and the second states the memory device is currently in, whereby the information read operation of the memory device is performed.

In the method of the present invention, preferably, the steps of magnetizing the one or more of the ferromagnetic thin films of the first memory element is carried out by using a magnetic filed, the magnetic field being generated by an electric current flowing through at least one of the first and the second wiring.

Further preferably, the step of magnetizing the one or more of the ferromagnetic thin films of the second memory element is carried out by using a magnetic filed, the magnetic field being generated by an electric current flowing through at least one of the second and the third wiring.

As described above, the nonvolatile semiconductor memory device constructed of the magnetoresistive elements according to the present invention is capable of being improved in electric current detection accuracy with respect to even as light variation in electric current which is smaller than that occurring in the prior art. This makes it possible for the memory device of the present invention to eliminate any resistance generating element which is an indispensable component to the conventional memory device. Further, since the memory cell of the nonvolatile semiconductor memory device of the present invention is simple in construction, it is possible to integrate a plurality of the memory cells of the present invention in an easy manner. Incidentally, though the memory cell of the nonvolatile semiconductor memory device of the present invention is constructed of two pieces of the memory elements stacked together vertically, there is no fear that the memory cell of the present invention increases its occupation area, which makes it possible for the memory device of the present invention to realize both a high density memory capacity and a more stable memory operation.

### BRIEF DESCRIPTION OF THE DRAWINGS

The above and other objects, advantages and features of the present invention will be more apparent from the following description taken in conjunction with the accompanying drawings in which:

FIG. 1(a) is a schematic perspective view of a memory cell in a nonvolatile semiconductor memory device according to a first embodiment of the present invention, illustrating the construction of memory elements of the memory cell;

FIG. 1(b) is a schematic perspective view of an essential part of the nonvolatile semiconductor memory device constructed of a plurality of the memory cells shown in FIG. 1(a), illustrating the construction of such an essential part;

FIG. 2(a) is a schematic perspective view of the essential part of the nonvolatile semiconductor memory device shown in FIG. 1(b), illustrating a data write operation thereof;

FIG. 2(b) is a schematic perspective view of the essential part of the nonvolatile semiconductor memory device shown in FIG. 1(b), illustrating a data read operation thereof;

FIG. 3 is a schematic perspective view of the nonvolatile semiconductor memory device according to a second embodiment of the present invention, illustrating the construction of the memory device;

FIG. 4(a) is a schematic perspective view of an essential part of the nonvolatile semiconductor memory device shown in FIG. 3, illustrating the construction of a memory cell thereof;

FIG. 4(b) is a schematic perspective view of the essential part of the nonvolatile semiconductor memory device shown in FIG. 4(a), illustrating a data read operation of the memory cell;

FIG. 4(c) is a schematic perspective view of the essential part of the nonvolatile semiconductor memory device shown in FIG. 4(a), illustrating a data write operation of the memory cell; and

FIG. 5 is a schematic perspective view of an essential part of the nonvolatile semiconductor memory device of a conventional type, illustrating the construction of such a conventional type memory device.

### DETAILED DESCRIPTION OF THE PREFERRED EMBODIMENTS

The best modes for carrying out the present invention will be described in detail using embodiments of the present invention with reference to the accompanying drawings.

The present invention may, however, be embodied in various different forms and should not be construed as limited to the embodiments set forth herein; rather, these embodiments are provided so that this disclosure will be thorough and complete, and will fully convey the scope of the present invention to those skilled in the art.

In the accompanying drawings, the thickness of films and regions are exaggerated for clarity. Like reference numerals refer to like parts throughout the drawings.

Incidentally, it will also be understood that when a layer or film is referred to as being “on” another film or substrate, it can be directly on such another film or substrate, or intervening films may also be present therebetween.

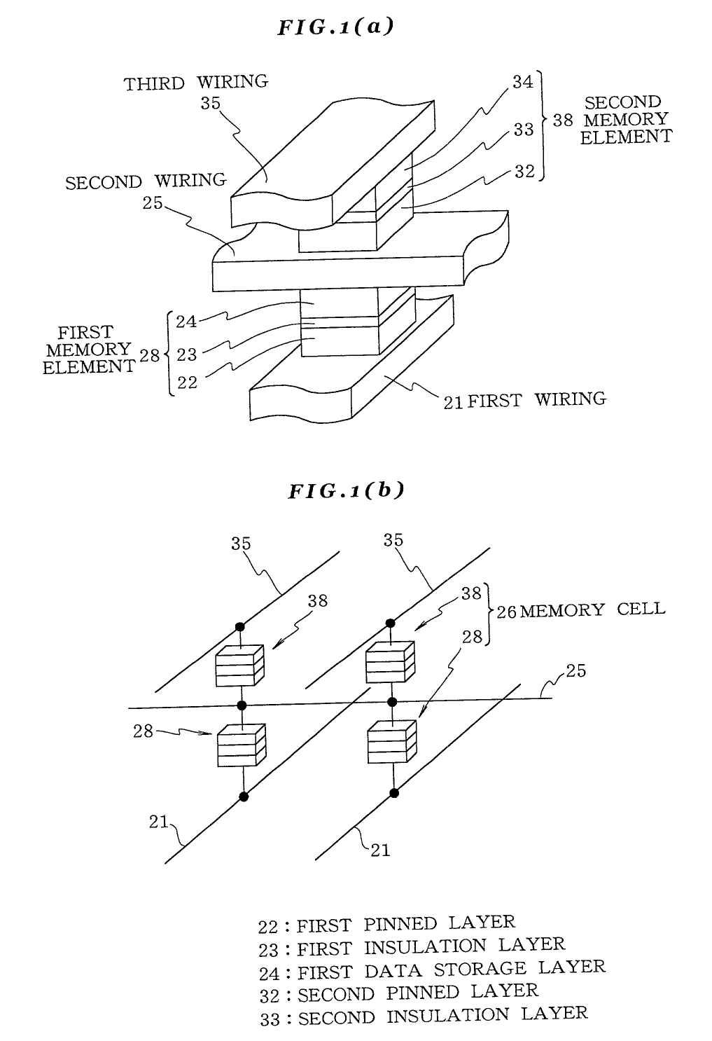

In the accompanying drawings: FIG. 1(a) shows a schematic perspective view of a memory cell of the MRAM according to a first embodiment of the present invention, illustrating the construction of memory elements of the memory cell; and, FIG. 1(b) shows a schematic perspective view of an essential part of the nonvolatile semiconductor memory device constructed of a plurality of the memory cells arranged in a lattice-like form and shown in FIG. 1(a), illustrating the construction of such an essential part of the memory device.

As shown in FIG. 1(a), in a memory cell of the nonvolatile semiconductor memory device of a first embodiment of the present invention, there is provided a first wiring 21 linearly extending in a first direction. A first fixed or pinned layer 22 has a thickness of approximately 20 nm, and is constructed of a ferromagnetic film a direction of magnetization of which remains fixed or pinned. On the other hand, a first insulation film 23 has a thickness of approximately 2 nm, and permits a tunnel current to flow the rethrough. This insulation film is disposed on the pinned layer 22 so as to be connected with the first pinned layer 22. Further, a first data storage layer 24 is disposed on the first insulation layer 23 so as to be connected with the first insulation layer 23. This first data storage layer 24 is constructed of a ferromagnetic thin film having a thickness of approximately 20 nm, and is capable of switching a direction of its magnetization. Further provided in the memory cell of the present invention is a second wiring 25, which is disposed on the first data storage layer 24 so as to be connected with the first data storage layer 24. This second wiring 25 linearly extends in a direction perpendicular to the first wiring 11. Still further provided in the memory cell is a second fixed or pinned layer 32 which is constructed of a ferromagnetic film having a thickness of approximately 20 nm. This second pinned layer 32 is fixed or pinned in its direction of magnetization and disposed at a predetermined position on the second wiring 25 so as to be connected with the second wiring 25. On the other hand, a second insulation layer 33 having a thickness of approximately 2 nm is disposed on the second pinned layer 32 so as to be connected with the second pinned layer 32, where by a tunnel current is permitted to flow through the second insulation layer 33. A second data storage layer 34 is disposed on the second insulation layer 33 so as to be connected with the second insulation layer 33, and is constructed of a ferromagnetic thin film having a thickness of approximately 20 nm and capable of being switched in its direction of magnetization. Further provided in the memory cell is a third wiring 35, which is disposed on the second data storage layer 34 so as to be connected with the second data storage layer 34. This third wiring 35 extends in a direction parallel to the first wiring 11. Incidentally, as parts of the memory cell, there are provided a first memory element 28 and a second memory element 38, wherein the first memory element 28 is constructed of the first pinned layer 22, the first insulation layer 23 and the first data storage layer 24 while the second memory element is constructed of the second pinned layer 32, the second insulation layer 33 and the second data storage layer 34. In the memory cell of the first embodiment, a bit of information is stored in the memory cell by using a pair of its first memory element 28 and its second memory element 38.

The nonvolatile semiconductor memory device of the first embodiment is constructed of a plurality of the memory cells which are arranged in a matrix form. Namely, as shown in FIG. 1(b), a plurality of the first wirings 21 each of which forms an underlying bit line are disposed on the first plane, and spaced apart from each other at equal intervals to extend in the same direction. On the other hand, a plurality of the second wirings 25 each of which forms a word line extending in a direction perpendicular to the underlying bit lines are disposed on the second plane arranged in parallel with the first plane, and are spaced apart from each other at equal intervals to extend in the same direction. Further provided in the memory cell is a plurality of the third wirings 35 each of which forms an overlying bit line are disposed on the third plane arranged in parallel with the second plane, and are spaced apart from each other at equal intervals to extend in the same direction as that of the first wirings 21. In the memory cell having the above construction, the second plane is disposed between the first and the third plane. In a plan view of the memory cell as viewed from a direction perpendicular to the first, the second and the third plane, the first wirings 21 overlie the third wirings 35. On the other hand, the first wirings 21 extend in a direction intersecting the second wirings 25 to form a lattice structure.

The first memory element 28 is disposed between the first wiring 21 and the second wiring 25 at their intersection. On the other hand, the second memory element 38 is disposed between the second wiring 25 and the third wiring 35 at their intersection. Due to such a lattice structure in the plan view, the first memory element 28 overlies the second memory element 38. One piece of the memory cell is constructed of one piece of the first memory element 28 and one piece of the second memory element 38. In the nonvolatile semiconductor memory device of the first embodiment, these memory cells are arranged in a lattice-like form, i.e., a form of matrix.

Further, connected with terminal portions of each of the first wiring 21, the second wirings 25 and the third wirings 35 are: a write circuit for storing information in the memory cell; and, a read circuit for retrieving the information thus stored in the memory cell.

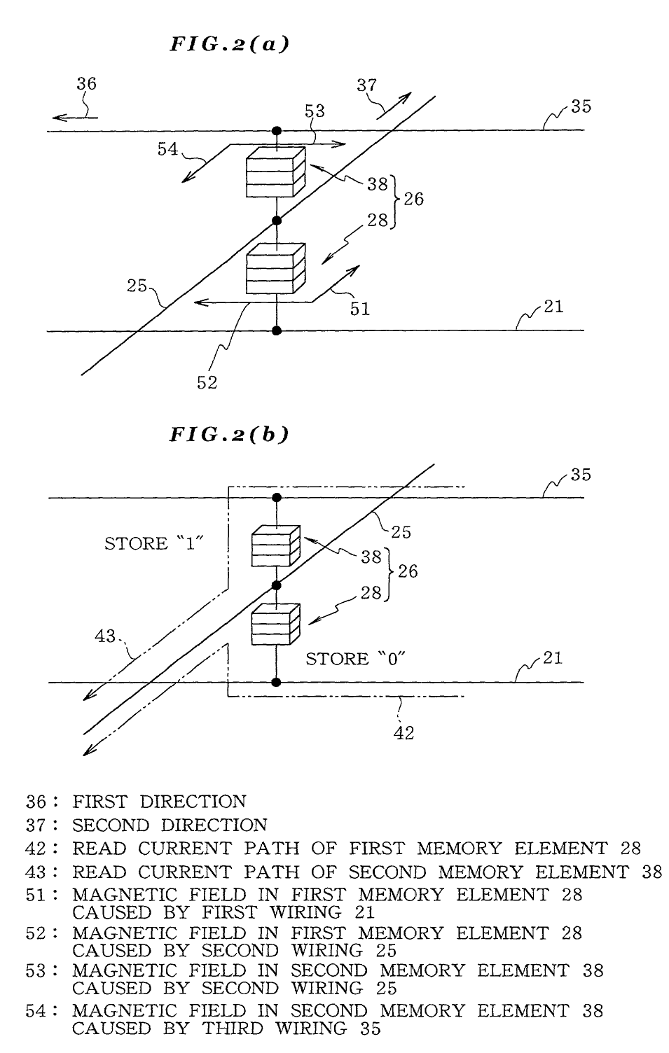

Now, the nonvolatile semiconductor memory device of the first embodiment will be described in operation. FIG. 2(a) shows a schematic perspective view of the essential part of the nonvolatile semiconductor memory device shown in FIG. 1(b), illustrating a data write operation thereof. FIG. 2(b) shows a schematic perspective view of the essential part of the nonvolatile semiconductor memory device shown in FIG. 1(b), illustrating a data read operation there of. Incidentally, for convenience of description, a word line 25 in addition to bit lines 35 and 21 disposed in an overlying and an underlying layer, respectively, are illustrated in FIGS. 2(a) and 2(b) as if these lines were replaced with each other in position.

First, a write operation of the memory device of the present invention will be described. First, as shown in FIG. 2(a), a predetermined electric current flows in the first direction 36 in each of the underlying bit line (i.e., the first wiring 21) and the overlying bit line (i.e., the third wiring 35). At this time, a predetermined electric current flows in the second direction 37 in the second wiring 25. As a result, these electric currents generate magnetic fields around each of the word wirings 25 and the bit lines 21, 35.

As shown in FIG. 2(a), in the first memory element 28, a magnetic field is generated in a direction 51 by the electric current flowing through the underlying bit line 21. On the other hand, a magnetic field is generated in a direction 52 by the electric current flowing through the word line 25. Consequently, the first memory element 28 is subjected to both of the above two magnetic fields generated in the directions 51, 52. On the other hand, as for the second memory element 28, a magnetic field is generated in a direction 54 by the overlying electric current. At the same time, another magnetic field is generated in a direction 53 by the electric current flowing through the word line 25. Consequently, the second memory element 38 is subjected to both of these magnetic fields generated in the directions 53, 54. As a result, the first memory element 28 is subjected to a magnetic field opposing in direction to a magnetic field to which the second memory element is subjected. On the other hand, a direction of magnetization of the ferromagnetic layer of the data storage layer 24 in the first memory element 28 is antiparallel to a direction of magnetization of the ferromagnetic layer of the data storage layer 34 in the second memory element 38. At this time, for example, when the direction of magnetization of each of the pinned layers of these memory elements is the same as that of the data storage layer 34 of the second memory element 38, a direction of magnetization of the data storage layer 24 of the first memory element 28 is antiparllel to that of the pinned layer 22 in a condition in which a direction of magnetization of the data storage layer 34 of the second memory element 38 is parallel to that of the pinned layer 32. The above state of the memory cell is defined and stored as a memory cell data “1”, for example.

In order to store another memory cell data “0”, for example, it is necessary to reverse in flow direction only the electric current flowing through the word line 25 in the above state defined as the memory cell data “1”. At this time, the electric current flowing through each of the overlying bit line and the underlying bit lines remains unchanged in flow direction, i.e., a flow direction of the electric current is the same as that in the case of the memory cell data “1”. As a result, it is clear that only the direction of the magnetic field generated by the electric current flowing through the word line 25 is reversed in comparison with the case of the memory data “1”. In the case where the easy axis in direction of magnetization of each of the first data storage layer 24 and the second data storage layer 34 is previously aligned with the first direction 36, it is possible to reverse in direction of magnetization the data storage layer of each of the first memory element 28 and the second memory element 38 in comparison with the case of the memory cell data “1”.

For example, in the case where a state of the second memory element 38 is in data “1” (in which the magnetroresistive value is small) while a state of the first memory element 28 is in data “0” (in which the magnetoresistive value is large), when such a pair of the states are defined as a memory cell data “1”, it is possible to change in state the second memory element 38 and the first memory element 28 into the data “0” and the data “1”, respectively, by reversing only in flow direction the electric current flowing through the word line 25. At this time, the pair of the states corresponds to the memory cell data “0”.

Next, a read operation of the memory device of the present invention will be described. In the nonvolatile semiconductor device of the first embodiment, as for the memory cells thereof, it is possible to select any one of the memory cells by selecting a predetermined one of each of the word lines 25, the overlying bit lines 35 and the underlying bit lines 21 after each of the memory cells perform a predetermined read operation in the array of the memory cells. After a desired one of the memory cells is selected, as shown in FIG. 2(b), it is possible to retrieve a stored piece of information by sensing a difference between the tunnel currents, wherein one of the tunnel currents flows between the word line 25 (i.e., the second wiring) and the overlying bit line 35 (i.e., the third wiring), while the other of the tunnel currents flows between the word line 25 and the underlying bit line 21 (i.e., the first wiring). In other words, a date read operation of the memory cell is performed by sensing a difference between the states stored in the first memory element 28 and the second memory element 38. Namely, in the state of the memory cell data “1” thus sensed, the first memory element 28 is larger in resistance than the second memory element 38. On the other hand, in the state of the memory cell data “0” thus sensed, the first memory element 28 is smaller in resistance than the second memory element 38.

In the first embodiment, information is stored in the memory element as is in the case of the prior art. In contrast with the prior art in which information is stored in one memory element and then the thus stored information is retrieved by sensing the absolute value of a tunnel current flowing through the memory element, in the memory device of the present invention, information is stored by using a pair of the first memory element 28 and the second memory element 38 while the information thus stored in the memory cell is retrieved by comparing the tunnel current flowing through the first memory element 28 with the tunnel current flowing through the second memory element 38. Due to this, it is possible to remarkably improve the memory device in its information read accuracy. Consequently, it is possible for the memory device of the present invention to perform the information read operation with high accuracy without using any high-accuracy resistance value generating element which is an indispensable component to the conventional memory device. Further, since each of the memory cell and the nonvolatile semiconductor memory device of the first embodiment of the present invention is simple in construction, it is possible to integrate a plurality of the memory cells of the present invention in an easy manner.

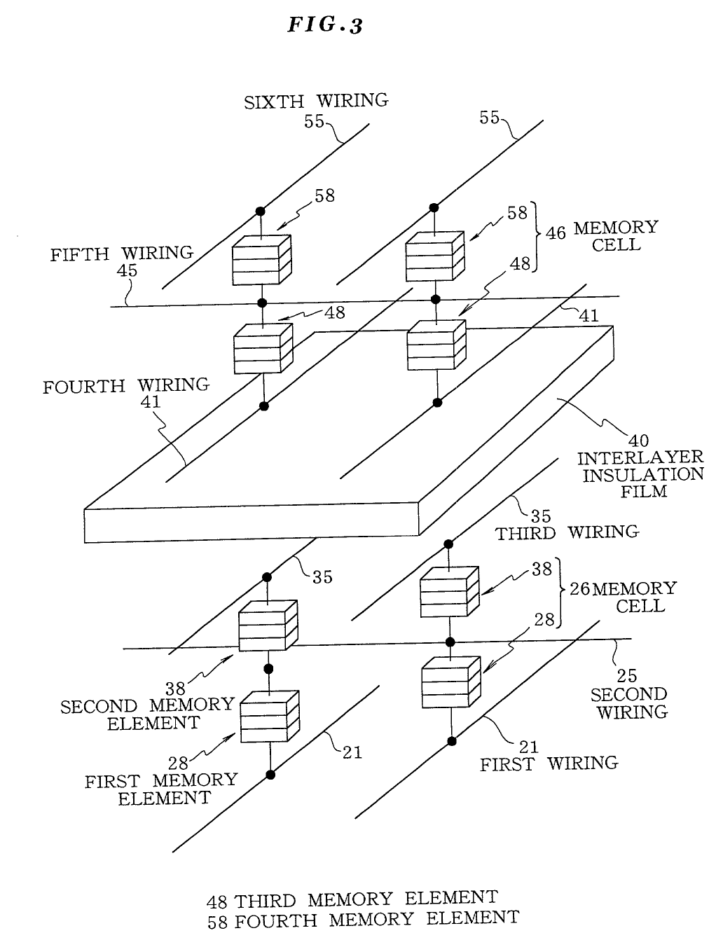

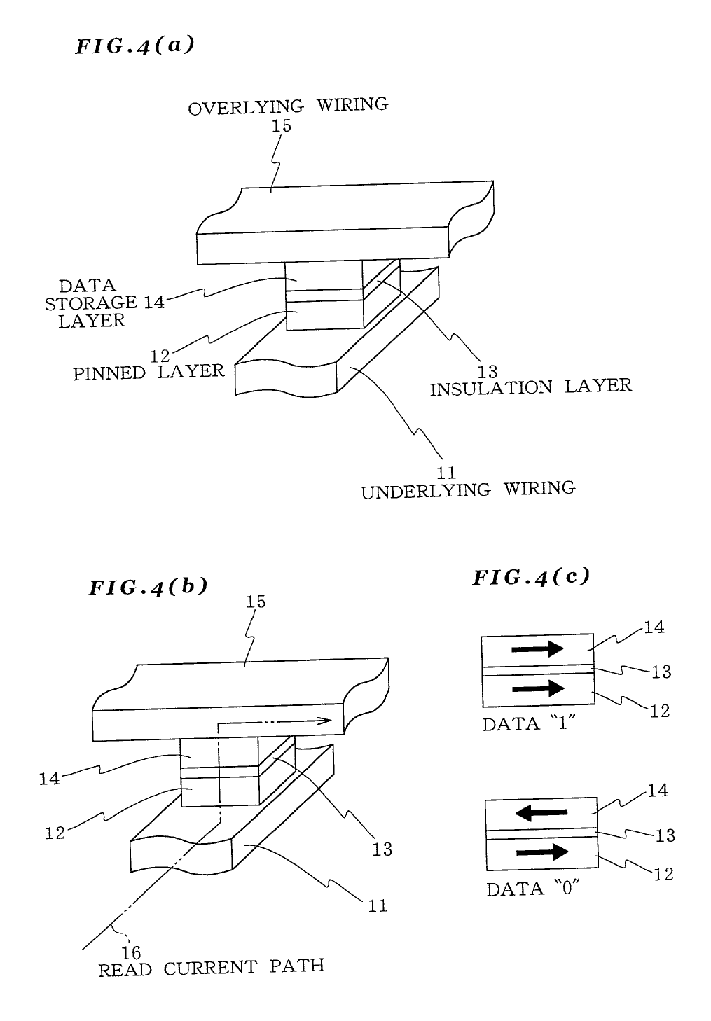

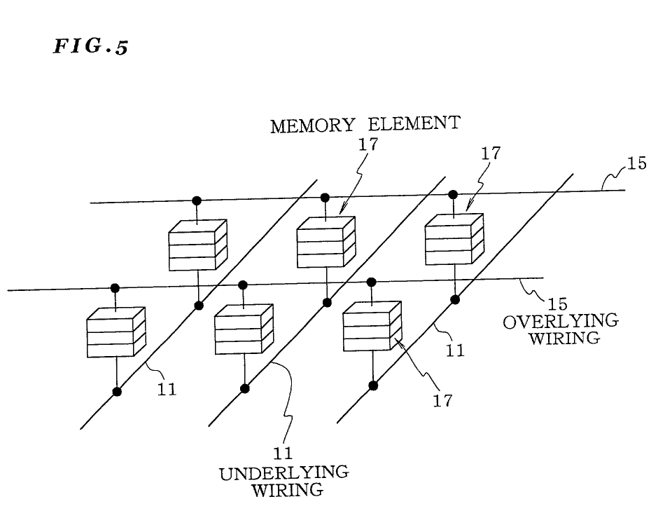

Now, a second embodiment of the present invention will be described. FIG. 3 shows a schematic perspective view of the nonvolatile semiconductor memory device (MRAM) according to the second embodiment of the present invention, illustrating the construction of the memory device. The nonvolatile semiconductor memory device of the second embodiment is characterized in that a group of the memory cells arranged in a lattice-like form in the first embodiment is disposed in each of opposite sides of an interlayer insulation film 40 as viewed in FIG. 3, in which the opposite sides are an upper and a lower side of the interlayer insulation film 40.

As shown in FIG. 3, the nonvolatile semiconductor memory device of the second embodiment has a construction in which: a plurality of the first wirings 21 are disposed on the first plane (not shown), and separated apart from each other at equal intervals to extend in parallel with each other; disposed on each of the first wirings 21 at equal intervals so as to be connected with the corresponding first wiring 21 are a plurality of the first memory elements 28 arranged in a lattice-like form; and, a plurality of the second wirings 25 are disposed on the corresponding first memory elements 28 so as to be connected with the corresponding first memory element 28. In the second embodiment having the above construction, the second wirings 25 are so arranged as to extend in a direction intersecting the first wirings 21 at right angles on the second plane (not shown) which is parallel to the first plane (not shown). Further, a plurality of the second memory elements 38 are disposed on the second wirings 25 so as to be connected to the second wirings 25, and are arranged in a lattice-like form. Further disposed on these second memory elements 38 so as to be connected with these second memory elements 38 are a plurality of the third wirings 35 disposed on the third plane (not shown) which is parallel to the first plane, so that the third wirings 35 extend in parallel with the first wirings 21 on the third plane. Still further disposed on the third wirings 35 so as to cover the third wirings 35 is the interlayer insulation film 40.

Further, arranged over the interlayer insulation film 40 are a plurality of fourth wirings 41 which are spaced apart from each other at equal intervals to extend in the same direction in parallel with the interlayer insulation film 40. Disposed on these fourth wirings 41 so as to be connected with the fourth wirings 41 are a plurality of third memory elements 48 which are arranged in a lattice-like form. Further disposed on these third memory elements 48 are a plurality of fifth wirings 45 so as to be connected with the third memory elements 48. In the above construction, the fifth wirings 45 are provided in a manner such that the fifth wirings 45 extend in a direction intersecting the fourth wirings 41 at right angles on a fifth plane (not shown) which is parallel to a surface of the interlayer insulation film 40. Further disposed on the fifth wirings 45 so as to be connected with the fifth wirings 45 are a plurality of fourth memory elements 58 arranged in a lattice-like form. Still further disposed on these fourth memory elements 58 are a plurality of sixth wirings 55 extending on a sixth plane (not shown) in parallel with the fourth wirings 41, wherein the sixth plane is parallel to the surface of the interlayer insulation film 40.

The nonvolatile semiconductor memory device of the second embodiment has the above construction. Due to this construction, it is possible for this second embodiment to double the packing density of the memory cells per unit area in comparison with that of the first embodiment of the nonvolatile semiconductor memory device. In the same way, it is also possible for the nonvolatile semiconductor memory device of the present invention to arrange three or more groups of the memory cells in each of an upper and a lower side of the interlayer insulation film 40, wherein the memory cells are arranged in a lattice-like form in each of their groups.

Incidentally, in the above embodiments, though the second wiring 25 intersects the first wiring 21 at right angles as viewed from above in the drawings (for example, in FIG. 3), it is not necessarily required to have the second wiring 25 intersect the first wiring at right angles. In other words, it is also possible for the second wiring 25 to intersect the first wiring 21 at any other angle other than the right angles.

Further, in the above embodiments, though the second plane is disposed between the first and the third plane, the relationship in location among these planes is not limited to only that illustrated in the embodiments. In other words, for example, it is also possible to arrange the first wiring 21 and the third wiring 35 in the same single plane, provided that it is necessary to have the relationship between the pinned layer 22 and the data storage layer 24 in the first memory element 28 and the relationship between the pinned layer 32 and the data storage layer 34 in the second memory element 28 differ from each other in direction of magnetization.

The invention may be embodied in other specific forms without departing from the spirit or essential characteristic thereof. The present embodiments are therefore to be considered in all respects as illustrative and not restrictive, the scope of the invention being indicated by the appended Claims rather than by the foregoing description and all changes which come within the meaning and range of equivalency of the Claims are therefore intended to be embraced therein.

The entire disclosure of Japanese Patent Application No. 2000-199590 (Filed on Jun. 30, 2000) including specification, claims, drawings and summary are incorporated herein by reference in its entirety.

What is claimed is:

1. A nonvolatile semiconductor memory device comprising:
a first wiring extending in a first direction;
a first memory element so arranged as to be connected with said first wiring;
a second wiring extending in a second direction which is different from said first direction, said second wiring being connected with said first memory element;
a second memory element so arranged as to be connected with said second wiring;
a third wiring extending in said first direction, said third wiring being connected with said second memory element;
wherein said first memory element is constructed of an insulation film and two or more of ferromagnetic thin films disposed adjacent to opposite sides of said insulation film, said ferromagnetic thin films being connected with said first wiring and said second wiring;
wherein said second memory element is constructed of an insulation film and two or more of ferromagnetic thin films disposed adjacent to opposite sides of said insulation film, said ferromagnetic thin films being connected with said second wiring and said third wiring;
wherein a difference in magnetization direction between said two or more of said ferromagnetic thin films is stored as a piece of information, said piece of information being retrieved by using variations in electric resistance value of said memory element when a tunnel current flows through said memory element, said variations in electric resistance value of said memory being caused by a magnetoresistive effect resulted from said difference in direction between said magnetizations of said two or more of said ferromagnetic thin films;
wherein said first memory element pairs off with said second memory element without exception to store a piece of information opposed in meaning to that stored in said second memory element.

2. The nonvolatile semiconductor memory device as set forth in claim 1, wherein
a plurality of each of said first, said second and said third wirings and a plurality of each of said first and said second memory elements are provided;
a write circuit connected with said first, said second and said third wiring to store said piece of information in both said first and said second memory element; and
a read circuit connected with said first, said second and said third wiring to retrieve said piece of information stored in said first and said second memory element.

3. The nonvolatile semiconductor memory device as set forth in claim 1, wherein said first direction is perpendicular to said second direction.

4. The nonvolatile semiconductor memory device as set forth in claim 2, wherein
said first wirings are arranged in parallel to each other on a first plane;
said second wiring are arranged in parallel to each other on a second plane, said second plane being parallel to said first plane and disposed over said first plane;
said third wirings are arranged in parallel to each other on a third plane, said third plane being parallel to said first plane and disposed over said second plane;
said first memory elements are disposed on a forth plane, said forth plane being parallel to said first plane and disposed between said first and said second plane;
said second memory elements are disposed on a fifth plane, said fifth plane being parallel to said first plane and disposed between said second and said third plane.

5. The nonvolatile semiconductor memory device as set forth in claim 2, wherein
each of said write circuit and said read circuit is constructed of a semiconductor integrated circuit.

6. The nonvolatile semiconductor memory device as set forth in claim 1, wherein
a plurality of groups, each group of which is constructed of said first, said second and said third wiring and said first and said second memory element, are arranged through said insulation films.

7. In a method for recording information in a nonvolatile semiconductor memory device comprising: a first wiring extending in a first direction; a first memory element so arranged as to be connected with said first wiring; a second wiring extending in a second direction which is different from said first direction, said second wiring being connected with said first memory element; a second memory element so arranged as to be connected with said second wiring; a third wiring extending in said first direction, said third wiring being connected with said second memory element;
wherein said first memory element is constructed of an insulation film and two or more of ferromagnetic thin films disposed adjacent to opposite sides of said insulation film, said ferromagnetic thin films being connected with said first wiring and said second wiring; said second memory element is constructed of an insulation film and two or more of ferromagnetic thin films disposed adjacent to opposite sides of said insulation film, said ferromagnetic thin films being connected with said second wiring and said third wiring; a difference in magnetization direction between said two or more of said ferromagnetic thin films is stored as a piece of information, said piece of information being retrieved by using variations in electric resistance value of said memory element when a tunnel current flows through said memory element, said variations in electric resistance value of said memory being caused by a magnetoresistive effect resulted from said difference in direction between said magnetizations of said two or more of said ferromagnetic thin films; said first memory element pairs off with said second memory element without exception to store a piece of information opposed in meaning to that stored in said second memory element,
the improvement therewith comprising the steps of:
magnetizing one or more of said ferromagnetic thin films of said first memory element in a direction parallel to or antiparallel to a direction of magnetization of the remaining ones of said ferromagnetic thin films other than said one or more of said ferromagnetic thin films to perform an information write operation in said nonvolatile semiconductor memory device; and
magnetizing one or more of said ferromagnetic thin films of said second memory element in a direction parallel to or antiparallel to a direction of magnetization of the remaining ones of said ferromagnetic thin films other than said one or more of said ferromagnetic thin films to perform said write operation of said piece of information in said nonvolatile semiconductor memory device;
wherein: one of a first state and a second state is selected to perform said write operation; said first state is established when said one or more of said ferromagnetic thin films of said first memory element are magnetized in a direction parallel to a direction of magnetization of the remaining ones of said ferromagnetic thin films of said first memory element in a condition in which said one or more of said ferromagnetic thin films of said second memory element are magnetized in a direction antiparallel to a direction of magnetization of the remaining ones of said ferromagnetic thin films of said second memory element; and, said second state is established when said one or more of said ferromagnetic thin films of said first memory element are magnetized in a direction antiparallel to a direction of magnetization of the remaining ones of said ferromagnetic thin films of said first memory element in a condition in which said one or more of said ferromagnetic thin films of said second memory element are magnetized in a direction parallel to a direction of magnetization of the remaining ones of said ferromagnetic thin films of said second memory element;
wherein an information read operation of said nonvolatile semiconductor memory device is performed through the steps of: determining a first electric resistance value of said first memory element when said tunnel current flows through said first memory element; determining a second electric resistance value of said second memory element when said tunnel current flows through said second memory element; and, sensing a difference in electric resistance value between said first and said second electric resistance value to determine which of said first and said second states said memory device is currently in, whereby said information read operation of said memory device is performed.

8. The method as set forth in claim 7, wherein said steps of magnetizing said one or more of said ferromagnetic thin films of said first memory element is carried out by using a magnetic filed, said magnetic field being generated by an electric current flowing through at least one of said first and said second wiring.

9. The method as set forth in claim 7, wherein said step of magnetizing said one or more of said ferromagnetic thin films of said second memory element is carried out by using a magnetic filed, said magnetic field being generated by an electric current flowing through at least one of said second and said third wiring.
